(19) United States
(12) Patent Application Publication
(10) Pub. No.: US 2019/0057977 A1
(43) Pub. Date: Feb. 21, 2019

(54) PIXEL UNIT, FABRICATION METHOD THEREOF, ARRAY SUBSTRATE, AND DISPLAY DEVICE

(71) Applicants: BOE TECHNOLOGY GROUP CO., LTD., Beijing (CN); HEFEI ZINSHENG OPTOELECTRONICS TECHNOLOGY CO., LTD., Hefei, Anhui (CN)

(72) Inventors: Xingfeng Ren, Beijing (CN); Lu Che, Beijing (CN); Lingling Zeng, Beijing (CN)

(73) Assignees: BOE TECHNOLOGY GROUP CO., LTD., Beijing (CN); HEFEI XINSHENG OPTOELECTRONICS TECHNOLOGY. CO., LTD., Hefei, Anhui (CN)

(21) Appl. No.: 15/767,515

(22) PCT Filed: Oct. 25, 2017
(86) PCT No.: PCT/CN2017/107628

§ 371 Date: Apr. 11, 2018

(30) Foreign Application Priority Data
Mar. 23, 2017 (CN) 201710180474.2

(51) Int. Cl. H01L 27/12; H01L 29/417; H01L 21/66; H01L 21/768; H01L 29/786; H01L 29/66

(52) U.S. Cl. CPC H01L 27/124; H01L 29/41733; H01L 27/1248; H01L 27/1288; H01L 27/1222; H01L 21/76894; H01L 29/78669; H01L 29/66765; H01L 22/14

(57) ABSTRACT

A pixel unit includes a thin film transistor, a first insulating layer, a pixel electrode, a second insulating layer, a meltable conductive component, and a common electrode. The thin film transistor includes a drain electrode. The first insulating layer is arranged over the drain electrode. The pixel electrode is arranged over the first insulating layer and electrically coupled to the drain electrode. The second insulating layer is arranged over the pixel electrode. The meltable conductive component is arranged over the second insulating layer. The common electrode is arranged over the meltable conductive component and electrically coupled to the meltable conductive component.

### CROSS-REFERENCE TO RELATED APPLICATION

This PCT patent application claims priority to Chinese Patent Application No. 201710180474.2, filed on Mar. 23, 2017, the entire contents of which are incorporated herein by reference.

### TECHNICAL FIELD

The present disclosure generally relates to the field of display technologies and, more particularly, to a pixel unit, a fabrication method thereof, an array substrate, and a display device.

### BACKGROUND

A display panel includes a plurality of pixel units. Due to deviation in a fabrication process, some pixel units may have bright dot defects. That is, the pixel units may exhibit as bright dots during displaying. During an operation of a display device containing the pixel units having bright dot defects, bright dots may be easily noticed by a viewer, and may result in a relatively poor viewing experience.

Generally, a pixel electrode and a common electrode of a pixel unit having a bright dot defect may be short-circuited, such that the pixel unit is turned into a dark dot. However, in the existing technology, a pixel electrode and a common electrode in a thin film transistor of a pixel unit have a minimal overlap, making it difficult to electrically couple the pixel electrode to the common electrode without affecting a normal display.

### SUMMARY

In one aspect, the present disclosure provides a pixel unit. The pixel unit includes a thin film transistor, a first insulating layer, a pixel electrode, a second insulating layer, a meltable conductive component, and a common electrode. The thin film transistor includes a drain electrode. The first insulating layer is arranged over the drain electrode. The pixel electrode is arranged over the first insulating layer and electrically coupled to the drain electrode. The second insulating layer is arranged over the pixel electrode. The meltable conductive component is arranged over the second insulating layer. The common electrode is arranged over the meltable conductive component and electrically coupled to the meltable conductive component.

Another aspect of the present disclosure provides a method for fabricating a pixel unit. The method includes providing a substrate, forming a thin film transistor including a drain electrode over the substrate, forming a first insulating layer over the drain electrode, forming a via hole in the first insulating layer, forming a pixel electrode over the first insulating layer, forming a second insulating layer over the pixel electrode and covering the pixel electrode, forming a meltable conductive component over the second insulating layer, and forming a common electrode over the meltable conductive component and electrically coupled to the meltable conductive component. An orthogonal projection of the via hole on the substrate at least partially overlaps with an orthogonal projection of the drain electrode on the substrate. The via hole penetrates through the first insulating layer along a thickness direction of the first insulating layer and exposing a portion of a surface of the drain electrode. A portion of the pixel electrode is in the via hole and is electrically coupled to the drain electrode. A portion of the second insulating layer is over the via hole. A portion of the meltable conductive component is over the via hole. The meltable conductive component and the pixel electrode are insulated from each other by the second insulating layer.

### BRIEF DESCRIPTION OF THE FIGURES

The following drawings are merely examples for illustrative purposes according to various disclosed embodiments and are not intended to limit the scope of the present disclosure.

FIG. 1 illustrates a schematic cross-sectional view of a pixel unit of a display panel;

FIG. 2A illustrates a schematic cross-sectional view of an exemplary pixel unit according to various disclosed embodiments of the present disclosure;

FIG. 2B illustrates a schematic view of the exemplary pixel unit after an exemplary conductive connector is formed by welding according to various disclosed embodiments of the present disclosure;

FIG. 3A illustrates a schematic view of an exemplary array substrate according to various disclosed embodiments of the present disclosure;

FIG. 3B illustrates a schematic view of an exemplary display device according to various disclosed embodiments of the present disclosure;

FIGS. 4A to 4G illustrate schematic views of exemplary structures at different stages of an exemplary fabrication method for an exemplary pixel unit according to various disclosed embodiments of the present disclosure;

FIG. 5 illustrates a flow chart of an exemplary fabrication method for an exemplary pixel unit according to various disclosed embodiments of the present disclosure; and

FIG. 6 illustrates a flow chart of an exemplary fabrication method for an exemplary thin film transistor of an exemplary pixel unit according to various disclosed embodiments of the present disclosure.

Reference numerals used in the drawings include: 100, thin film transistor; 110, drain electrode; 120, source electrode; 130, active layer; 140, gate electrode; 200, pixel electrode; 300, 300′, common electrode; 400, common electrode line; 500, first insulating layer; 600, second insulating layer; 700, conductive connector; 800, substrate; 920, array substrate; 921, pixel unit; 930, display device; 931, display panel; and 499, passivation layer.

### DETAILED DESCRIPTION

Exemplary embodiments of the disclosure will now be described in more detail with reference to the drawings. It is to be noted that, the following descriptions of some embodiments are presented herein for purposes of illustration and description only, and are not intended to be exhaustive or to limit the scope of the present disclosure.

The aspects and features of the present disclosure can be understood by those skilled in the art through the exemplary embodiments of the present disclosure further described in detail with reference to the accompanying drawings.

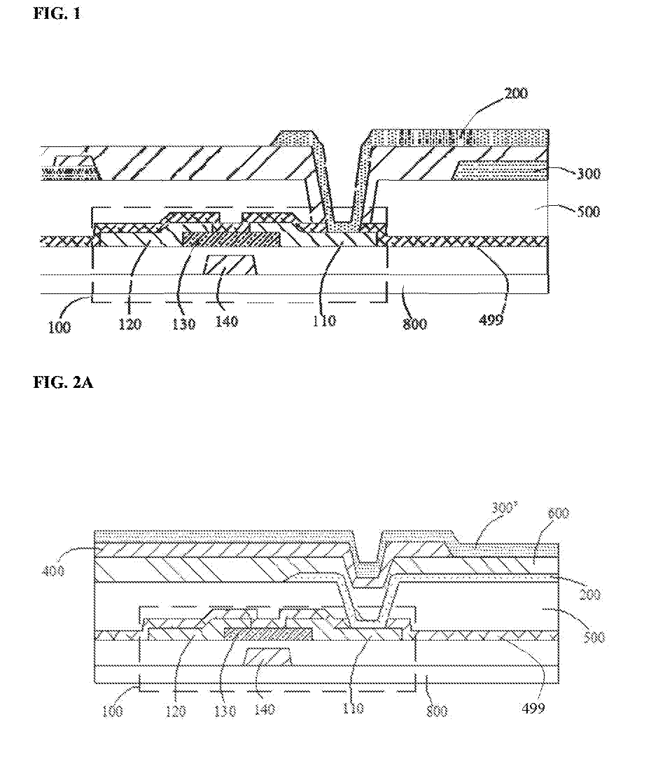

FIG. 1 illustrates a schematic cross-sectional view of a pixel unit of a display panel. As shown in FIG. 1, the pixel unit includes a thin film transistor 100, a pixel electrode 200, a common electrode 300, and a first insulating layer 500 formed over a substrate 800. The thin film transistor 100 includes a drain electrode 110, a source electrode 120, an active layer 130, and a gate electrode 140. The gate electrode 140 and the active layer 130 are separated and electrically insulated. The pixel unit further includes a passivation layer 499 formed over the thin film transistor 100. The first insulating layer 500 may be configured to reduce parasitic capacitances and a line delay. Generally, the first insulating layer 500 may be formed by a transparent resin material. The pixel electrode 200 is electrically coupled to the drain electrode 110 of the thin film transistor 100 through a via hole penetrating through the first insulating layer 500. Some pixel units may have bright dot defects, because of deviation in a fabrication process.

A bright dot may be caused by various reasons. For example, in a pixel unit, the thin film transistor may include a heavily-doped semiconductor layer formed of n+a-Si, and thus may have a relatively large electrical conductivity and a relatively high shutdown current. When the thin film transistor is turned off, a portion of charges may be conducted through the heavily-doped semiconductor layer, resulting in a relatively low pixel voltage, and thus a bright dot may be formed. As another example, a bright dot defect may be caused by a short circuit between a source electrode and a drain electrode in a pixel unit, an open circuit between a source electrode and a drain electrode in a pixel unit, or a failure to electrically couple a pixel electrode and a drain electrode of a thin film transistor due to a defective via hole for coupling the pixel electrode to the drain electrode of the thin film transistor, or another related reason. Generally, in a pixel unit having a bright dot defect, a pixel electrode and a common electrode may be short-circuited to convert the pixel unit into a dark dot.

However, as shown in FIG. 1, an overlapping between the pixel electrode 200 and the common electrode 300 is minimal, making it difficult to electrically couple the pixel electrode 200 to the common electrode 300 without affecting a normal display.

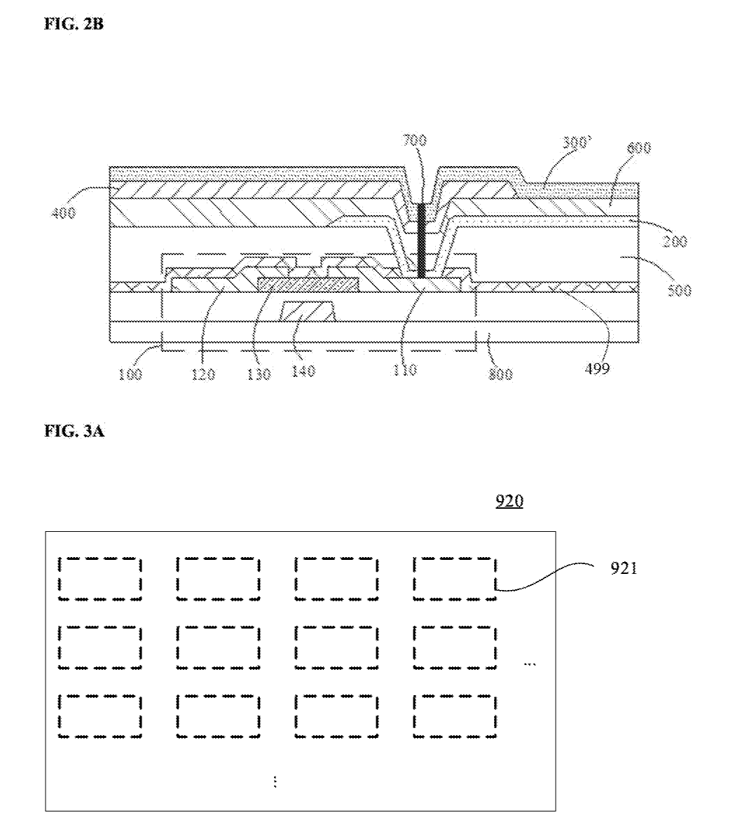

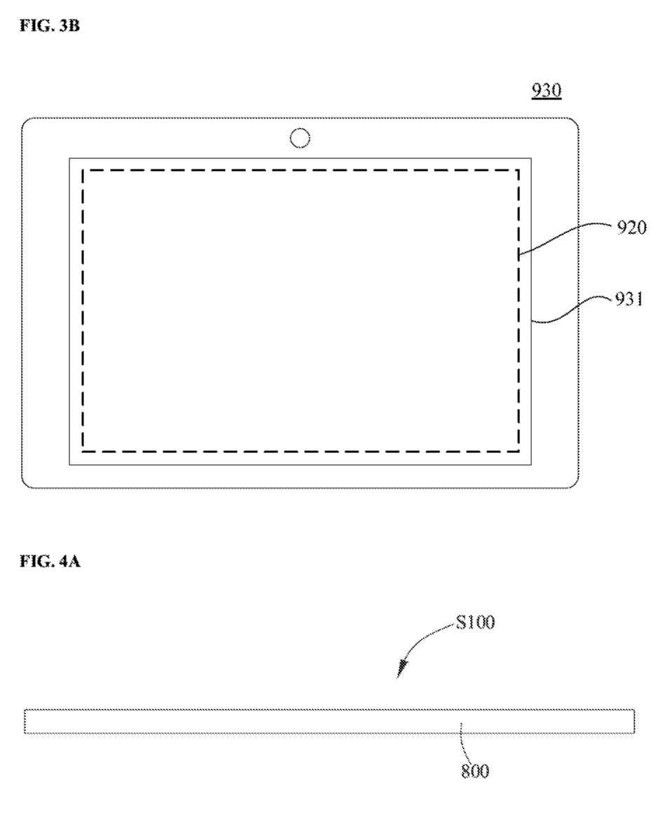

FIG. 2A illustrates a schematic cross-sectional view of an exemplary pixel unit according to various disclosed embodiments of the present disclosure. As shown in FIG. 2A, the pixel unit includes the thin film transistor 100, the pixel electrode 200, a common electrode 300′, a common electrode line 400, the first insulating layer 500, and a second insulating layer 600. The common electrode line 400 is electrically coupled to the common electrode 300′. The first insulating layer 500 is arranged between a layer in which the drain electrode 110 of the thin film transistor 100 is located and a layer in which the pixel electrode 200 is located. That is, the first insulating layer 500 is arranged between the drain electrode 110 of the thin film transistor 100 and the pixel electrode 200. The pixel electrode 200 is electrically coupled to the drain electrode 110 through the via hole penetrating through the first insulating layer 500. The second insulating layer 600 is arranged between the pixel electrode 200 and the common electrode line 400 to electrically insulate the pixel electrode 200 from the common electrode line 400. Further, a portion of the second insulating layer 600 and a portion of the common electrode line 400 are located over the via hole.

The pixel unit of the disclosure can be applied to an array substrate of a display device. When the pixel unit has a bright dot defect, the common electrode line 400, the pixel electrode 200, and the drain electrode 110 of the thin film transistor 100 in the pixel unit having the bright dot defect may be electrically coupled to each other by an appropriate method, e.g., laser welding. Because the common electrode line 400 may generally be made of a metallic material, the common electrode line 400 may have a relatively large thickness. Further, the drain electrode 110 may be made of a metal material. Before welding, a structure at the via hole may include a “metal+pixel electrode+metal” sandwich structure. In some embodiments, the pixel electrode can be, for example, a transparent electrode. In response to welding, molten metal material can form a conductive connector 700, as shown in FIG. 2B and described in more detail below.

FIG. 2B illustrates a schematic view of the exemplary pixel unit after an exemplary conductive connector is formed by welding according to various disclosed embodiments of the present disclosure. As shown in FIG. 2B, in response to welding, molten metal material forms the conductive connector 700. The conductive connector 700 may form a stable electrical coupling to the pixel electrode 200 and to the drain electrode 110 in the pixel unit.

In the pixel unit, the common electrode line 400 may provide a common voltage signal to the common electrode 300′. Thus, after the common electrode line 400 is electrically coupled to the pixel electrode 200 by welding, the common electrode line 400 can provide the common voltage signal to the pixel electrode 200. Accordingly, the pixel unit having a bright dot defect may be converted into a dark dot, such that a normal display of the display device may be maintained.

In some other embodiments, turning the pixel unit having a bright dot defect into a black dot can also be performed by welding in a region outside the via hole area to electrically couple the common electrode line 400 to the pixel electrode 200.

In the present disclosure, a material of the common electrode line 400 is not restricted. For example, the common electrode line 400 may be made of any one selected from a group including copper, aluminum, and molybdenum, or may be made of an alloy formed by at least two selected from the group including copper, aluminum, and molybdenum.

In the present disclosure, a structure of the thin film transistor 100 is not restricted. In some embodiments, the thin film transistor 100 may be a top-gate type thin film transistor. In some other embodiments, the thin film transistor 100 may be a bottom-gate type thin film transistor. In the embodiments shown in FIGS. 2A and 2B, the thin film transistor 100 is a bottom-gate type thin film transistor. As shown in FIGS. 2A and 2B, the thin film transistor 100 includes the gate electrode 140, the active layer 130, the source electrode 120, and the drain electrode 110. A gate insulating layer is arranged between the gate electrode 140 and the active layer 130. The source electrode 120 is electrically coupled to the active layer 130. The drain electrode 110 is electrically coupled to the active layer 130.

Generally, the common electrode 300′ may overlap with the common electrode line 400. For example, in the embodiments shown in FIGS. 2A and 2B, the common electrode 300′ is located over the common electrode line 400. Such a pixel unit has an increased contact area between the common electrode 300′ and the common electrode line 400 and a reduced extension distance of the common electrode line 400 to an open region, e.g., a display region, of the pixel unit. As a result, a stable electrical coupling between the common electrode 300′ and the common electrode line 400 can be formed to facilitate provision of a common electrode signal to the common electrode 300′ and an aperture ratio of an array substrate employing the pixel unit can be increased.

As described above, because a portion of the common electrode line may be located over the via hole, when the pixel unit has a bright dot defect, the common electrode line, the pixel electrode, and the drain electrode in the via hole can be welded together, such that the pixel unit can be turned into a dark dot. If the number of repaired pixel units in an array substrate is within an allowable range, the array substrate can still be regarded as a good product. FIGS. 2A and 2B illustrate schematic views of a portion of a pixel unit before and after a repair, respectively. As shown in FIG. 2B, the repaired pixel unit includes a conductive connector 700. The conductive connector 700 penetrates through a portion of the common electrode line 400 located over the via hole, a portion of the second insulating layer 600 located over the via hole, and a portion of the pixel electrode 200 located in the via hole, such that the common electrode line 400 is electrically coupled to the drain electrode 110 of the thin film transistor 100 in the defective pixel unit, i.e., the pixel unit having a bright dot defect.

Because both the common electrode line 400 and the drain electrode 110 may include metal materials and may have relatively large thicknesses, a conductive connector 700 of a suitable size may be formed to form a stable electrical coupling.

In the present disclosure, a material of the first insulating layer 500 and a material of the second insulating layer 600 are not restricted. In some embodiments, the first insulating layer 500 may be a planarization layer of the pixel unit, and the material of the first insulating layer 500 may include, for example, any one selected from or a combination of any several selected from a group including an alkyd resin, an acrylic resin, a polyethylene, a polystyrene, a polyester resin, a polyamide resin, and a phenolic resin. The second insulating layer 600 may be a passivation layer of the pixel unit. The material of the second insulating layer 600 may include, for example, silicon oxide, i.e., SiOx, or silicon nitride, i.e., SiNy, or a combination of silicon oxide and silicon nitride. The first insulating layer 500 may be made of an organic material, and thus a parasitic capacitance of the array substrate can be reduced. The pixel electrode 200 can be better protected by using the passivation layer as the second insulating layer 600. In addition, in some embodiments, only the second insulating layer 600 made of an inorganic material is included between the common electrode line 400 and the pixel electrode 200, and the first insulating layer 500 made of an organic material is not included between the common electrode line 400 and the pixel electrode 200. Thus, when the bright dot defect is being repaired, the common electrode line 400 and the pixel electrode 200 can be smoothly welded.

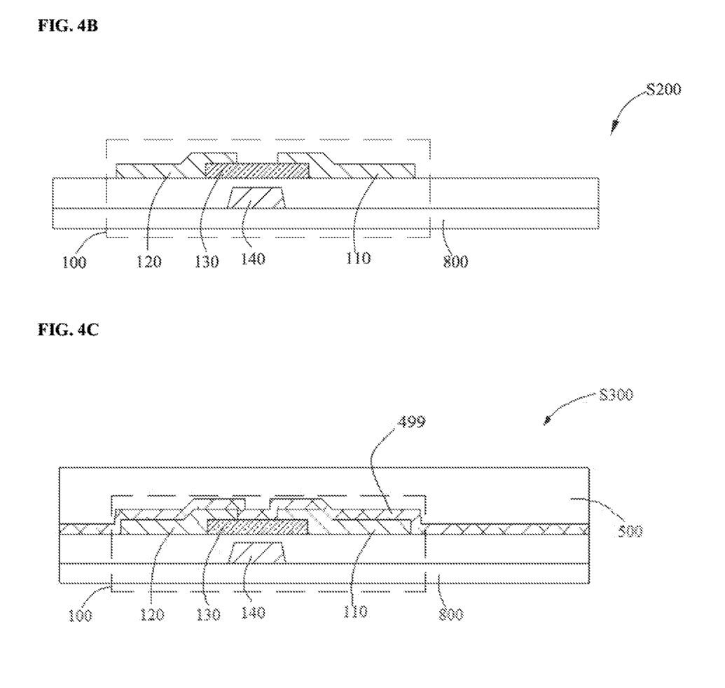

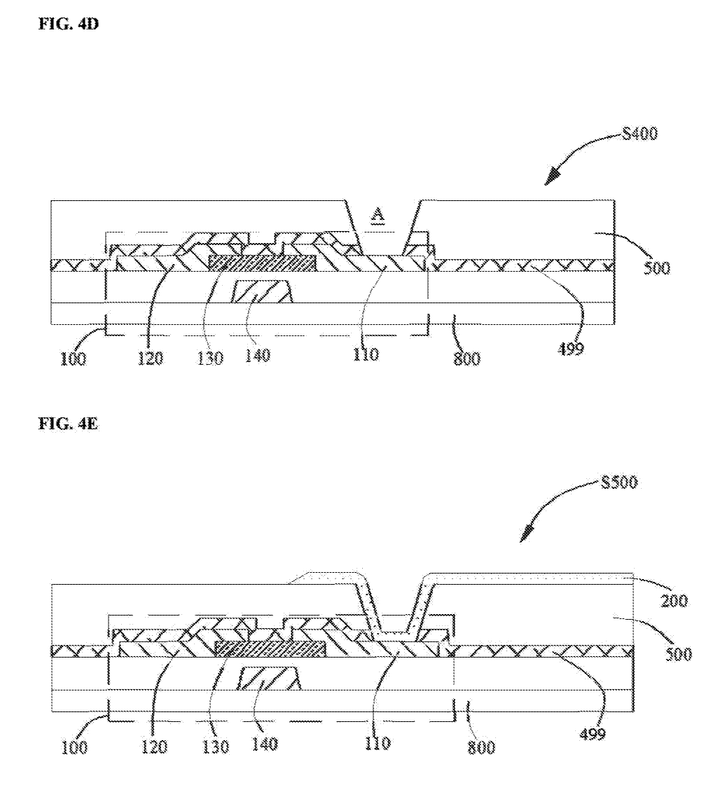

The present disclosure further provides an array substrate. FIG. 3A illustrates a schematic view of an exemplary array substrate 920 according to various disclosed embodiments of the present disclosure. As shown in FIG. 3A, the array substrate 920 includes a plurality of pixel units in which at least one pixel unit 921 is the pixel unit consistent with the disclosure. The pixel unit 921 can be any one of the pixel units consistent with the present disclosure, such as one of the exemplary pixel units described above. Any array substrate including a pixel unit consistent with the disclosure is within the scope of the present disclosure.

After the array substrate including the pixel unit of the disclosure is fabricated, the array substrate may be tested. If a pixel unit has the bright dot defect, welding can be performed at the via hole of the pixel unit having the bright dot defect to form a connector and to convert the pixel unit having the bright dot defect into a dark dot.

In some embodiments, each pixel unit of the array substrate may be the pixel unit consistent with the disclosure. In some other embodiments, only some of pixel units of the array substrate may be the pixel units consistent with the disclosure.

In some embodiments, first insulating layers of multiple pixel units in the array substrate may include portions of one insulating layer, and second insulating layers of multiple pixel units in the array substrate may include portions of another insulating layer.

In some embodiments, common electrode lines of multiple pixel units in a same row may include portions of a one electrode layer.

The present disclosure further provides a display device including an array substrate of the disclosure. FIG. 3B illustrates a schematic view of an exemplary display device 930 according to various disclosed embodiments of the present disclosure. As shown in FIG. 3B, the display device 930 includes an array substrate 920 consistent with the disclosure. In addition to the array substrate 920, the display device 930 may further include other suitable structures. For example, as shown in FIG. 3B, the display device 930 includes a display panel 931, which further includes the array substrate 920.

In the present disclosure, the type of the display device is not restricted. The display device can be, for example, a mobile phone, a computer, a tablet computer, an electronic paper, a global position system (GPS) navigator, or any suitable product or component having a display function. Any display device including an array substrate consistent with the disclosure is within the scope of the present disclosure.

When a defective pixel unit having a bright dot defect in the array substrate is identified in a testing process, in the defective pixel unit, the pixel electrode may be short-circuited with the common electrode to form a dark dot. In some embodiments, a portion of the common electrode line may be located over the via hole. Thus, when the conductive connector for short-circuiting the pixel electrode and the common electrode is formed by welding, molten metal material may be sufficient to form a reliable electrical coupling.

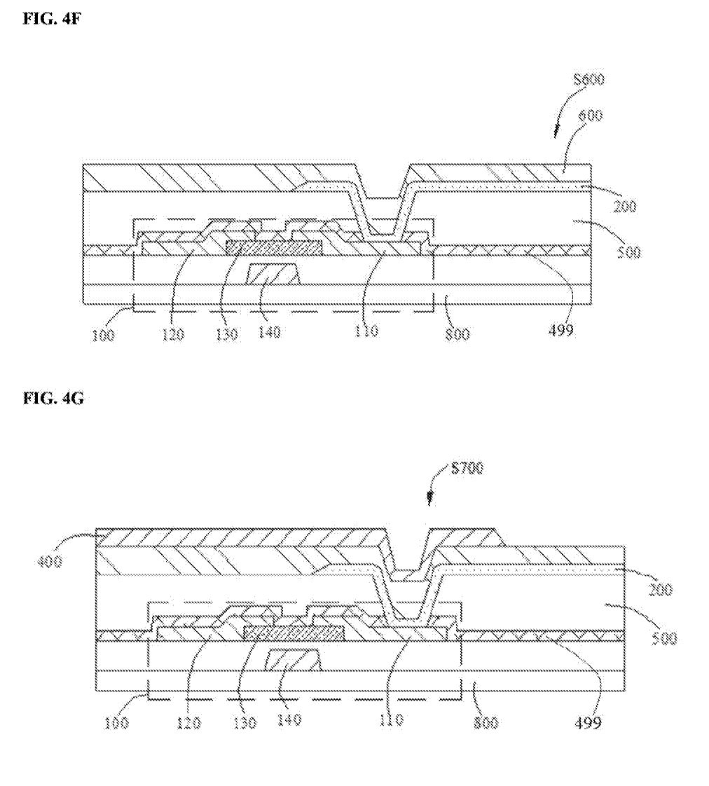

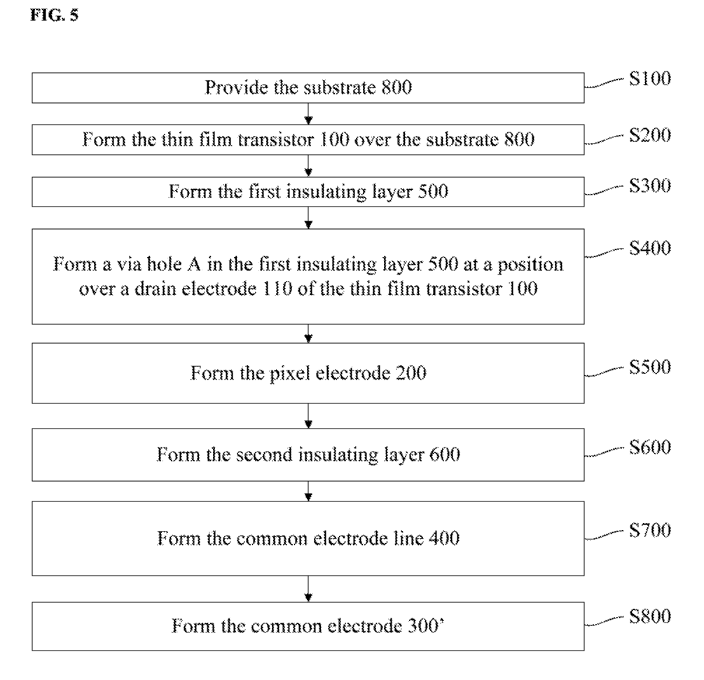

The present disclosure further provides a fabrication method for the pixel unit of the disclosure. FIGS. 4A to 4G illustrate schematic views of exemplary structures at different stages of an exemplary fabrication method for an exemplary pixel unit according to various disclosed embodiments of the present disclosure. FIG. 5 illustrates a flow chart of an exemplary fabrication method for an exemplary pixel unit according to various disclosed embodiments of the present disclosure. The fabrication method is described below with reference to FIG. 4A to FIG. 4G, and FIG. 5.

At S100, the substrate 800 is provided, as shown in FIG. 4A.

At S200, the thin film transistor 100 is formed over the substrate 800, as shown in FIG. 4B.

At S300, the first insulating layer 500 is formed, as shown in FIG. 4C.

At S400, a via hole A is formed in the first insulating layer 500 at a position over a drain electrode 110 of the thin film transistor 100, as shown in FIG. 4D. That is, the via hole A is formed in the first insulating layer 500, and an orthogonal projection of the via hole A on the substrate at least partially overlaps with an orthogonal projection of the drain electrode 110 on the substrate. The via hole A penetrates through the first insulating layer 500 along a thickness direction of the first insulating layer 500, and exposes a portion of the surface of the drain electrode 110.

At S500, the pixel electrode 200 is formed, as shown in FIG. 4E. A portion of the pixel electrode 200 is located in the via hole, and the pixel electrode 200 is electrically coupled to the drain electrode 110.

At S600, the second insulating layer 600 is formed, as shown in FIG. 4F. A portion of the second insulating layer 600 is located over the via hole, and the second insulating layer covers the pixel electrode 200.

At S700, the common electrode line 400 is formed, as shown in FIG. 4G. A portion of the common electrode line 400 is located over the via hole, and the common electrode line 400 and the pixel electrode 200 are electrically insulated by the second insulating layer 600.

At S800, the common electrode 300′ is formed, as shown in FIG. 2A. The common electrode 300′ is electrically coupled to the common electrode line 400, and an initial pixel unit is formed.

In the present disclosure, the manner of forming the via hole A is not restricted, and may be selected according to various application scenarios. In some embodiments, the first insulating layer may be an organic insulating layer, and accordingly, the via hole A may be formed by a photolithography process. That is, a mask plate may be arranged over the first insulating layer, and the first insulating layer may be exposed to light. Then, a development process may be applied to the first insulating layer after the light exposure, and the via hole A can be formed.

In the present disclosure, the manner of forming the common electrode line is not restricted, and may be selected according to various application scenarios. In some embodiments, a metal layer may be formed over the second insulating layer by a sputter process, and then a pattern including the common electrode line may be formed by using a photolithography patterning process.

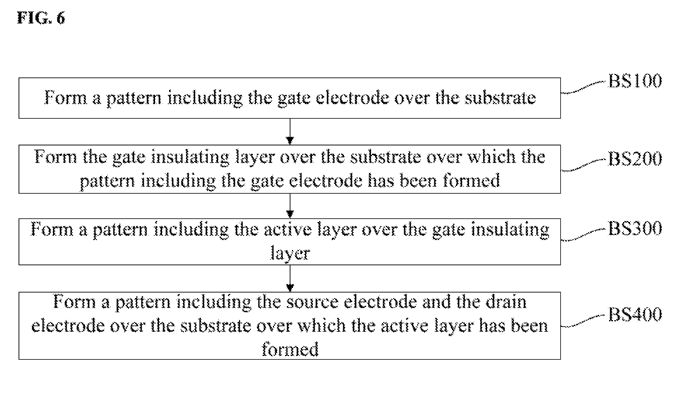

As shown in FIG. 2A, the thin film transistor 100 includes the gate electrode 140, the active layer 130, the source electrode 120, and the drain electrode 110. The thin film transistor 100 may be formed by a patterning process. For example, the bottom-gate type thin film transistor in FIG. 4B can be formed as the following, with reference to FIG. 6. FIG. 6 illustrates a flow chart of an exemplary fabrication method for an exemplary thin film transistor of an exemplary pixel unit according to various disclosed embodiments of the present disclosure.

At BS100, a pattern including the gate electrode 140 is formed over the substrate 800.

At BS200, the gate insulating layer is formed over the substrate over which the pattern including the gate electrode has been formed.

At BS300, a pattern including the active layer 130 is formed over the gate insulating layer.

At BS400, a pattern including the source electrode 120 and the drain electrode 110 is formed over the substrate over which the active layer 130 has been formed.

In some embodiments, as shown in, e.g., FIGS. 2A and 2B, and 4C-4G, a passivation layer 499 is formed over the thin film transistor 100 to protect the source electrode 120 and the drain electrode 110 of the thin film transistor 100. Accordingly, in order to expose the upper surface of the drain electrode 110, the via hole A may also need to penetrate through the passivation layer 499.

In some embodiments, the initial pixel unit can be, for example, a final product. That is, in some embodiments, the initial pixel unit can be the pixel unit of the disclosure.

In some other embodiments, the initial pixel unit may be further processed to form the pixel unit of the disclosure.

In the present disclosure, the sequence of forming the common electrode and forming the common electrode line is not restricted, and may be selected according to various application scenarios. For example, in disclosed embodiments, a pattern including the common electrode line may be formed before a pattern including the common electrode is formed. In some other embodiments, a pattern including the common electrode line may be formed after a pattern including the common electrode is formed.

As shown in FIG. 2A, the common electrode 300′ is overlapped with the common electrode line 400.

A material of the first insulating layer may include, for example, any one selected from or a combination of any several selected from the group including an alkyd resin, an acrylic resin, a polyethylene, a polystyrene, a polyester resin, a polyamide resin, and a phenolic resin. A material of the second insulating layer may include silicon oxide or silicon nitride, or a combination of silicon oxide and silicon nitride.

As shown in FIG. 2A, a portion of the common electrode line is located over the via hole, and thus the pixel unit can be easily converted into a dark dot. Accordingly, the fabrication method may further include testing the initial pixel unit.

If the initial pixel unit has a bright dot defect, the method may further include forming a conductive connector in the initial pixel unit to form a pixel unit. The conductive connector may penetrate through the second insulating layer and the pixel electrode to electrically couple the portion of the common electrode line over the via hole in the initial pixel to the drain electrode in the initial pixel unit.

After the common electrode line is electrically coupled to the drain electrode in the initial pixel unit having a bright dot defect, the initial pixel unit can be converted into a dark dot, and a normal display of a display device may be maintained.

In the present disclosure, the manner of forming the conductive connector is not restricted. In some embodiments, forming the conductive connector in the initial pixel unit may include forming the conductive connector by laser welding.

In some embodiments of the present disclosure, the common electrode line may provide the molten metal material for forming the conductive connector, which is merely for illustrative purposes and does not limit the scope of the present disclosure. In the present disclosure, a component that provides the molten metal material for forming the conductive connector is not restricted. Any meltable conductive component can provide the molten metal material for forming the conductive connector. In some embodiments, the meltable conductive component can be, for example, the common electrode line, a portion of the common electrode line, or a component (such as a line or a layer) disposed in a same layer as the common electrode line. In some other embodiments, the meltable conductive component can be, for example, a component other than the common electrode line.

The present disclosure provides a pixel unit, a fabrication method thereof, an array substrate, and a display device. The pixel unit may include a thin film transistor, a pixel electrode, a first insulating layer, a second insulating layer, a common electrode and a common electrode line. The common electrode line may be electrically coupled to the common electrode. The first insulating layer may be arranged between a drain electrode of the thin film transistor and the pixel electrode. The pixel electrode may be electrically coupled to the drain electrode through a via hole penetrating through the first insulating layer. The second insulating layer may be arranged between the pixel electrode and the common electrode line to electrically insulate the pixel electrode from the common electrode line. In addition, a portion of the second insulating layer and a portion of the common electrode line may be located over the via hole. In the present disclosure, if the pixel unit has a bright dot defect, the pixel unit may be converted into a dark dot by performing a repair.

The foregoing description of the embodiments of the disclosure has been presented for purposes of illustration and description. It is not intended to be exhaustive or to limit the disclosure to the precise form or to exemplary embodiments disclosed. Accordingly, the foregoing description should be regarded as illustrative rather than restrictive. Obviously, many modifications and variations will be apparent to persons skilled in this art. The embodiments are chosen and described in order to explain the principles of the technology, with various modifications suitable to the particular use or implementation contemplated. It is intended that the scope of the invention be defined by the claims appended hereto in which all terms are meant in their broadest reasonable sense unless otherwise indicated. Therefore, the term “the disclosure,” “the present disclosure,” or the like does not necessarily limit the claim scope to a specific embodiment, and the reference to exemplary embodiments of the disclosure does not imply a limitation on the invention, and no such limitation is to be inferred. Moreover, the claims may refer to “first,” “second,” etc., followed by a noun or element. Such terms should be understood as a nomenclature and should not be construed as giving the limitation on the number of the elements modified by such nomenclature unless specific number has been given. Any advantages and benefits described may or may not apply to all embodiments of the disclosure. It should be appreciated that variations may be made to the embodiments described by persons skilled in the art without departing from the scope of the present disclosure. Moreover, no element or component in the present disclosure is intended to be dedicated to the public regardless of whether the element or component is explicitly recited in the following claims.

1. A pixel unit, comprising:
a thin film transistor including a drain electrode,
a first insulating layer over the drain electrode;
a pixel electrode over the first insulating layer and electrically coupled to the drain electrode;
a second insulating layer over the pixel electrode;
a meltable conductive component over the second insulating layer; and
a common electrode over the meltable conductive component and electrically coupled to the meltable conductive component.

2. The pixel unit according to claim 1, wherein:
the meltable conductive component includes a common electrode line.

3. The pixel unit according to claim 2, wherein:
a portion of the pixel electrode is in a via hole penetrating the first insulating layer and electrically coupled to the drain electrode; and
a portion of the second insulating layer and a portion of the common electrode line are over the via hole.

4. The pixel unit according to claim 3, further comprising:
a conductive connector penetrating the portion of the common electrode line over the via hole, the portion of the second insulating layer over the via hole, and the portion of the pixel electrode in the via hole to electrically couple the common electrode line to the drain electrode.

5. The pixel unit according to claim 2, wherein the common electrode overlaps with the common electrode line.

6. The pixel unit according to claim 2, wherein the common electrode line is made of at least one of copper, aluminum, or molybdenum.

7. The pixel unit according to claim 2, wherein the common electrode line includes an alloy formed by at least two selected from the group including copper, aluminum, and molybdenum.

8. The pixel unit according to claim 1, wherein the thin film transistor further includes:
an active layer,
a source electrode arranged at one side of the active layer and electrically coupled to the active layer, and
a gate electrode electrically insulated from the active layer,
wherein the drain electrode is arranged at another side of the active layer and electrically coupled to the active layer.

9. The pixel unit according to claim 1, further comprising:
a passivation layer over the thin film transistor and beneath the first insulating layer.

10. The pixel unit according to claim 1, wherein:
a material of the first insulating layer includes any one selected from or a combination of any several selected from a group including an alkyd resin, an acrylic resin, a polyethylene, a polystyrene, a polyester resin, a polyamide resin, and a phenolic resin, and
a material of the second insulating layer includes at least one selected from a group including silicon oxide and silicon nitride.

11. An array substrate, comprising a plurality of pixel units, wherein at least one of the plurality of pixel units includes the pixel unit according to claim 1.

12. A display device, comprising the array substrate according to claim 11.

13. A method for fabricating a pixel unit, comprising:
providing a substrate;
forming a thin film transistor including a drain electrode over the substrate;
forming a first insulating layer over the drain electrode;
forming a via hole in the first insulating layer, an orthogonal projection of the via hole on the substrate at least partially overlapping with an orthogonal projection of the drain electrode on the substrate, the via hole penetrating through the first insulating layer along a thickness direction of the first insulating layer and exposing a portion of a surface of the drain electrode;
forming a pixel electrode over the first insulating layer, a portion of the pixel electrode being in the via hole and electrically coupled to the drain electrode;
forming a second insulating layer over the pixel electrode and covering the pixel electrode, a portion of the second insulating layer being over the via hole;
forming a meltable conductive component over the second insulating layer, a portion of the meltable conductive component being over the via hole, and the meltable conductive component and the pixel electrode being insulated from each other by the second insulating layer; and
forming a common electrode over the meltable conductive component and electrically coupled to the meltable conductive component.

14. The method according to claim 13, wherein forming the meltable conductive component includes forming a common electrode line.

15. The method according to claim 13, wherein the common electrode overlaps with the common electrode line, and a portion of the common electrode is over the via hole.

16. (canceled)

17. The method according to claim 13, wherein the common electrode line includes an alloy formed by at least two selected from the group including copper, aluminum, and molybdenum.

18. The method according to claim 13, wherein the thin film transistor further includes:
an active layer,
a source electrode arranged at one side of the active layer and electrically coupled to the active layer, and
a gate electrode electrically insulated from the active layer,
wherein the drain electrode is arranged at another side of the active layer and electrically coupled to the active layer.

19. The method according to claim 13, wherein:
a material of the first insulating layer includes any one selected from or a combination of any several selected from a group including an alkyd resin, an acrylic resin, a polyethylene, a polystyrene, a polyester resin, a polyamide resin, and a phenolic resin, and
a material of the second insulating layer includes at least one selected from a group including silicon oxide and silicon nitride.

20. The method according to claim 13, further comprising:
conducting a test to determine whether a bright dot defect exists; and
forming, if the bright dot defect exists, a conductive connector penetrating through the second insulating layer and the pixel electrode such that the portion of the common electrode line over the via hole is electrically coupled to the drain electrode.

21. The method according to claim 20, wherein forming the conductive connector includes conducting a laser welding to form the conductive connector.
